(19) United States
(12) Patent Application Publication
(10) Pub. No.: US 2007/0137686 A1
(43) Pub. Date: Jun. 21, 2007

(54) Differential temperature energy harvesting in a fuel cell powered underwater vehicle

(75) Inventors: Michael Richard Durling, Moreau, NY (US); Benjamin Walter Hojnacki, Alameda, CA (US)

Correspondence Address: Paul J. Esatto, Jr.;Scully, Scott, Murphy & Presser, 400 Garden City Plaza, Garden City, NY, 11530, US

(73) Assignee: Lockheed Martin Corporation, Bethesda, MD (US)

(21) Appl. No.: 11/300,986

(22) Filed: Dec. 15, 2005

(51) Int. Cl. H01L 35/30; H01L 35/34

(52) U.S. Cl. 136/205; 136/201

(57) ABSTRACT

A method and apparatus for harvesting energy in a fuel cell powered vehicle has first and second energy harvesting elements with at least two ends, the first end being electrically insulated from and in thermal communication with a high temperature reservoir associated with the fuel cell, the second end being electrically insulated from and in thermal communication with a low temperature reservoir associated with an exterior of the vehicle. The apparatus has particular utility for use in watercraft, specifically an underwater vehicle. The energy harvesting apparatus can include an electrical storage means for storing the energy harvested, and/or an electric load for consuming the energy harvested.

### BACKGROUND OF THE INVENTION

1. Field of Invention

The present invention relates generally to the field of vehicle power plants, and more specifically to a fuel cell powered underwater vehicle having a differential temperature energy-harvesting device.

2. Description of Related Art

Fuel cell power plants are becoming more highly developed in the art and are preferable in part because of their low emissions characteristics. In addition, fuel cells operating on hydrogen and oxygen are a good choice for underwater vehicle power because they feature both a high energy density, measured as kilowatt-hours per liter of volume (kW·hr/L), and high specific energy, measured as kilowatt-hours per kilogram (kW·hr/kg). Either of these characteristics enable construction and operation of vehicles having the added flexibility of increased mission duration for a given store of energy, and/or achieving a predetermined mission duration using a reduced energy storage requirement over alternative energy sources.

However, fuel cells have as a drawback the fact that they generate a significant amount of waste heat. For example, fuel cells typically operate at approximately 50% efficiency, which means that for every Watt of electrical power generated, they produce one Watt of waste heat. In order to operate in an underwater environment, it is necessary to dissipate this waste heat through a heat exchanger, which transfers the heat to the surrounding seawater. This heat energy is therefore lost to the environment.

### BRIEF SUMMARY OF THE INVENTION

In order to overcome this and other drawbacks, deficiencies and shortcomings in the prior art, provided according to the present invention is an apparatus for harvesting energy in a fuel cell powered vehicle having first and second energy harvesting elements with at least two ends, the first end being electrically insulated from and in thermal communication with a high temperature reservoir associated with the fuel cell, the second end being electrically insulated from and in thermal communication with a low temperature reservoir associated with an exterior of the vehicle. In a preferred embodiment, the vehicle is a watercraft, specifically an underwater vehicle. The energy harvesting apparatus can include an electrical storage means for storing the energy harvested, and/or an electric load for consuming the energy harvested.

Also provided according to the present invention is a method for harvesting energy in a fuel cell powered vehicle comprising providing first and second energy harvesting elements having at least two ends, the first end being electrically insulated from and in thermal communication with a high temperature reservoir associated with the fuel cell, the second end being electrically insulated from and in thermal communication with a low temperature reservoir associated with an exterior of the vehicle, and directing an electrical voltage generated across the first and second energy harvesting elements to either an energy management system, electrical storage means, or electrical load.

### BRIEF DESCRIPTION OF THE DRAWINGS

These and other features, aspects and benefits of the present invention will be made apparent with reference to the following specification and accompanying drawings, where like reference numerals refer to like features across the several views, and wherein:

FIG. 1 illustrates a schematic of a differential temperature energy harvesting in a fuel cell powered underwater vehicle according to the present invention.

### DETAILED DESCRIPTION OF THE INVENTION

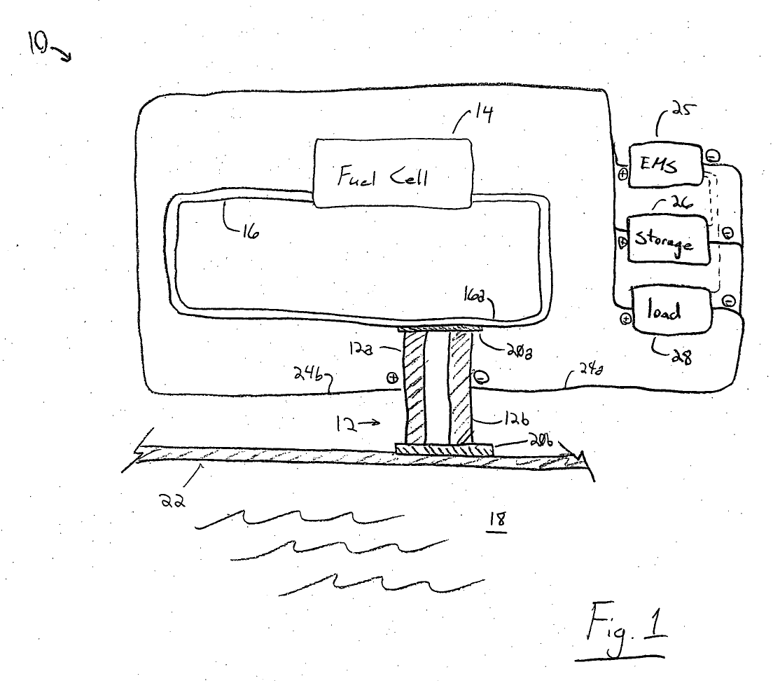

Referring now to FIG. 1, shown in schematic form is the power plant section, generally 10, of an underwater vehicle having a differential temperature energy-harvesting unit, generally 12. Power plant section 10 has at its core a fuel cell 14, operative to produce electricity directly from hydrogen and oxygen. The specific type of fuel cell 14 will vary with the particular application, and may include, without limitation, Proton Exchange Membrane (PEM), Alkaline, or Solid Oxide types. Each type will have a particular operating temperature, which in turn will affect design considerations as will be shown, infra.

Power plant section 10 has a heat exchange loop 16 associated with fuel cell 14. A cooling medium is circulated through the heat exchange loop 16 in order to carry waste heat away from the fuel cell 14. Provided between an elevated temperature section 16a of the heat exchange loop 16 and the surrounding seawater is the differential temperature thermoelectric energy harvesting unit 12, alternately referred to as a Seebeck unit, so named for Russian-German physicist Thomas Seebeck (1770-1831).

Energy harvesting unit 12 comprises one or more pairs (one in the exemplary embodiment) of dissimilar elements 12a, 12b, and both elements of the (one or more) pairs together spanning the distance between elevated temperature section 16a of heat exchange loop 16 and a low temperature reservoir 18. In a preferred embodiment, the elements 12a, 12b are comprised of materials considered semiconductors. In any case, the materials comprising each element 12a, 12b are selected to have a differential between the Seebeck coefficients of the two materials. One of the elements, 12a, will be a p-type leg, while the other, 12b, will be an n-type leg.

As examples, but in no way limiting the scope of the invention, material including lead telluride (PbTe), silver-antimony-germanium telluride (TAGS), and silicon germanium (SiGe) are frequently used in thermoelectric conversion. For example, telluride-based thermoelectric devices are advantageous when used in combination with relatively lower-temperature fuel cell types, including PEM or Alkaline. Silicon germanium thermoelectric devices are advantageous when used in combination with relatively high temperature fuel cell, including a Solid Oxide type.

At each of the thermal extremes, the energy-harvesting unit 12 has electrical insulation 20a, 20b from the respective temperature reservoir. Under the influence of the of the temperature differential (ΔT) between the elevated temperature section 16a of heat exchange loop 16 and a low temperature reservoir 18, the metals will, according to the Seebeck effect, generate a voltage across the junction. This voltage may be captured via positive and negative nodes 24a and 24b, respectively, and directed to one or more of an energy management system 25, a storage means 26, including capacitive, solid state, chemical, battery, or other energy storage apparatus for later use, and/or directed to an internal or external electric load 28 associated with the vehicle.

In an alternative embodiment comprising a plurality of dissimilar pairs, these may be arranged electrically in series or in parallel as required according to the particular application. Moreover, the material forming either of the first and second energy harvesting elements can include a dopant material, for example gallium phosphorous (GaP), to enhance the production of electric energy.

In yet another alternative embodiment, energy harvesting unit 12 comprises a thermocouple circuit, in which the junctions of two dissimilar metals are maintained at respectively high and low temperatures. Thereby, a voltage differential is produced between the two temperature reservoirs along either of the metals, which can be harvested.

In the exemplary embodiment low temperature reservoir 18 is the seawater surrounding the hull 22 of the underwater vessel. In most operational environments, it is expected that the temperature of the surrounding seawater will be significantly lower than that of the fuel cell 14 or the elevated temperature portion 16a of heat exchange loop 16. For example, a fuel cell 14 of the PEM type will operate at a temperature of approximately 60 degrees Celsius, while a fuel cell 14 of the solid oxide type will operate at a temperature of approximately 950 degrees Celsius. In comparison, the seawater temperature surrounding the underwater vessel can be expected to range between approximately 5 and 35 degrees Celsius. The energy produced will be proportional to the temperature differential (ΔT) across the energy harvesting unit 12. Accordingly, fuel cell types which operate at a higher temperature will yield a greater level of output from energy harvesting unit 12.

The exemplary embodiment has been described with reference to an underwater vehicle. However, the present invention is equally applicable to surface watercraft, using the water in contact with the hull of the watercraft as a low temperature reservoir. Alternately, the present invention can be applied to surface vehicles designed to traverse land, water or either (e.g., ground-effect vehicles or hovercraft), where by operation of the fuel cell a sufficient temperature differential with the ambient environment can be expected in order to yield production of electrical energy in accordance with the present invention.

The present invention has been described with reference to certain exemplary embodiments. These embodiments are offered solely as illustrative, and not limiting, of the scope of the invention. Certain alterations and modifications will be apparent to those skilled in the art in light of the instant disclosure, without departing from the scope of the invention, which is defined solely by the appended claims.

1. An apparatus for harvesting energy in a fuel cell powered vehicle comprising:
first and second energy harvesting elements, the first and second energy harvesting elements having a difference between their respective Seebeck coefficients, each of the first and second elements having at least two ends, the first ends being in thermal communication with a high temperature reservoir associated with the fuel cell, the second ends being in thermal communication with a low temperature reservoir associated with an exterior of the vehicle.

2. The apparatus according to claim 1, wherein the high temperature reservoir comprises a high temperature section of a heat exchange loop in thermal communication with the fuel cell.

3. The apparatus according to claim 1, wherein the vehicle is a watercraft, and the low temperature reservoir is water surrounding the watercraft.

4. The apparatus according to claim 3, wherein the watercraft is an underwater vehicle.

5. The apparatus according to claim 1 further comprising a plurality of pairs of said first and second energy harvesting elements.

6. The apparatus according to claim 5 wherein the plurality of pairs are in parallel electric communication with each other.

7. The apparatus according to claim 5 wherein the plurality of pairs are in series electric communication with each other.

8. The apparatus according to claim 1 wherein either or both first and second energy harvesting elements further comprises a dopant material.

9. The apparatus according to claim 1 wherein the fuel cell is selected from a group comprising Proton Exchange Membrane (PEM), Alkaline, and Solid Oxide type fuel cells.

10. The apparatus according to claim 1 further comprising an electrical storage means in electric communication with the first and second energy harvesting elements.

11. The apparatus according to claim 1 further comprising an electric load in electric communication with the first and second energy harvesting elements.

12. The apparatus according to claim 1 further comprising an energy management system in electric communication with the first and second energy harvesting elements.

13. The apparatus according to claim 1 wherein the first ends of the first and second energy harvesting elements are electrically insulated from the high temperature reservoir.

14. The apparatus according to claim 1 wherein the second ends of the first and second energy harvesting elements are electrically insulated from the low temperature reservoir.

15. A method for harvesting energy in a fuel cell powered vehicle comprising:
(a) providing first and second energy harvesting elements having a difference between their respective Seebeck coefficients, each element having at least two ends, the first ends being in thermal communication with a high temperature reservoir associated with the fuel cell, the second ends being in thermal communication with a low temperature reservoir associated with an exterior of the vehicle; and
(b) directing an electrical voltage generated across the first and second energy harvesting elements to one or more of an energy management system, electrical storage means, or electric load.

16. The method according to claim 15, wherein the fuel cell powered vehicle comprises a watercraft.

17. The method according to claim 16, wherein the watercraft comprises an underwater vehicle.

18. The method according to claim 15, further comprising electrically insulating the first ends of the first and second energy harvesting elements from the high temperature reservoir.

19. The method according to claim 15, further comprising electrically insulating the second ends of the first and second energy harvesting elements from the low temperature reservoir.

20. A method for harvesting energy in a fuel cell powered vehicle having first and second energy harvesting elements, the first and second energy harvesting elements having at least two ends, the first ends being in thermal communication with the fuel cell, the second ends being in thermal communication with a low temperature reservoir, the method comprising:
(a) energizing a high temperature reservoir with waste heat derived from the fuel cell; and
(b) directing an electrical voltage generated across the first and second energy harvesting elements to one or more of an energy management system, electrical storage means, or electric load.
